(19) United States
(12) Patent Application Publication
(10) Pub. No.: US 2026/0180456 A1
(43) Pub. Date: Jun. 25, 2026

(54) DYNAMIC DUTY CYCLE CONTROL STRATEGY FOR DC-DC CONVERTERS

(71) Applicant: Caterpillar Inc., Peoria, IL (US)

(72) Inventors: Zeljko R. Jankovic, Mequon, WI (US); Srevidhya Devi, Chennai (IN); Likhita Ravuri, Peoria, IL (US); Jyothiraditya Ramaswamy, Anupuram (IN); Ahmed Khalil, Dunlap, IL (US); Jackson Wai, Dunlap, IL (US); James Thorne, Peoria, IL (US)

(73) Assignee: Caterpillar Inc., Peoria, IL (US)

(21) Appl. No.: 18/989,530

(22) Filed: Dec. 20, 2024

(51) Int. Cl. H02M 3/335; B60L 15/00; H02M 1/00; H03K 7/08

(52) U.S. Cl. CPC H02M 3/33573; B60L 15/007; H02M 1/0058; H02M 3/33584; H03K 7/08; B60L 2200/40; B60L 2210/10

(57) ABSTRACT

Techniques are described that address the unequal loss distribution between switches in the top half and the bottom half of the primary side full bridge circuit of the H bridge of two-level SAB and DAB converters. The techniques involve dynamically controlling the duty cycles of power switches in the top and the bottom switches of the primary side full bridge circuit and, as a result, balancing their temperature. In particular, the duty cycles of the switches may be “toggled” after N cycles of an operating cycle pattern so as to invert the duty cycles of the complementary switches. Inverting the duty cycles of the complementary switches reverses (or “toggles”) the duty cycles between the complementary switch pairs. By implementing this approach, the techniques achieve a balanced loss distribution between the two halves, thereby facilitating higher power density operation.

### FIELD OF THE DISCLOSURE

This document pertains generally, but not by way of limitation, to isolated DC-DC converters.

### BACKGROUND

Single Active Bridge (SAB) and Dual Active Bridge (DAB) converters are types of DC-DC converters used in high-efficiency power conversion applications. SAB is a general converter topology that encompasses variations such as the Phase-Shifted Full Bridge (PSFB). Both SAB and DAB converters are suitable for a wide range of applications requiring efficient power conversion. These converters utilize phase-shifting techniques to achieve zero-voltage switching (ZVS) and/or zero-current switching (ZCS), which reduces switching losses and improves overall efficiency. Their ability to handle power flow makes them ideal for applications such as renewable energy systems, energy storage systems, and electric vehicle (EV) charging infrastructure.

The SAB converter is a versatile topology that may be implemented with various control strategies to optimize performance based on specific application requirements. Common implementations include a single full bridge on the primary side paired with a rectifier bridge on the secondary side, similar to the structure of a PSFB. Control methods for SAB converters may range from phase-shift techniques to duty cycle control, frequency modulation, or resonant control, depending on the design objectives. This flexibility allows SAB converters to be tailored for applications requiring efficient power conversion with low switching losses and high reliability.

The DAB converter includes two active bridges, one on the primary side and one on the secondary side, allowing for efficient bidirectional power transfer. The phase shift between the switches residing on the two bridges (primary and secondary bridge) controls the power flow and could achieve soft switching (ZVS and/or ZCS) in both directions. The control of a DAB converter involves managing the phase shift between two active bridges to regulate power flow in both directions. This requires more complex control algorithms to ensure efficient and stable operation, especially during transitions between charging and discharging modes.

US20140177281A1 is directed to a power converting system that includes a full-bridge converter and a controlling unit. The full-bridge converter includes two switch elements at a first leg and two switch elements at a second leg. The controlling unit is in communication with the full-bridge converter for generating two leading control signals to control the first leg and two lagging control signals to control the second leg in a first modulation mode, or generating the two leading control signals to control the second leg and the two lagging control signals to control the first leg in a second modulation mode. The first modulation mode and the second modulation mode are alternately switched between each other, or randomly switched between each other or adaptively switched between each other according to a temperature difference between the first leg and the second leg.

### SUMMARY OF THE DISCLOSURE

This disclosure describes techniques that address the unequal loss distribution between switches in the top half and the bottom half of the primary side full bridge circuit of the H bridge of two-level SAB and DAB converters, The techniques involve dynamically controlling the duty cycles of power switches in the top and the bottom switches of the primary side full bridge circuit and, as a result, balancing their temperature. In particular, the duty cycles of the switches may be “toggled” after N cycles of an operating cycle pattern so as to invert the duty cycles of the complementary switches. Inverting the duty cycles of the complementary switches reverses (or “toggles”) the duty cycles between the complementary switch pairs. By implementing this approach, the techniques achieve a balanced loss distribution between the two halves, thereby facilitating higher power density operation.

In some aspects, this disclosure is directed to a two-level DC-DC converter comprising: a primary side full bridge circuit including: a first leg having a first electronic switch and a second electronic switch; and a second leg having a third electronic switch and a fourth electronic switch, wherein the third electronic switch and the fourth electronic switch have complementary switching operations, wherein configurations of the first electronic switch, the second electronic switch, the third electronic switch, and the fourth electronic switch define an operating cycle pattern for the primary side full bridge circuit, and wherein the primary side full bridge circuit is configured to generate a first voltage; and a secondary side power stage circuit including a second plurality of electronic components, the secondary side power stage circuit configured to generate a second voltage; a transformer coupled between the primary side full bridge circuit and the secondary side power stage circuit; and a control circuit configured for: controlling duty cycles of the first electronic switch and the second electronic switch of the first leg such that a duty cycle of one of the first electronic switch and the second electronic switch is greater than 50%, wherein the first electronic switch and the second electronic switch have complementary duty cycles; controlling duty cycles of the third electronic switch and the fourth electronic switch of the second leg, such that a duty cycle of one of the third electronic switch and the fourth electronic switch is greater than 50%, wherein the third electronic switch and the fourth electronic switch have complementary duty cycles; and after N cycles of the operating cycle pattern: inverting the duty cycles of the first electronic switch and the second electronic switch of the first leg; and inverting the duty cycles of the third electronic switch and the fourth electronic switch of the second leg.

In some aspects, this disclosure is directed to a control circuit for a two-level DC-DC converter, the two-level DC-DC converter including a primary side full bridge circuit having a first leg having a first electronic switch and a second electronic switch, and a second leg having a third electronic switch and a fourth electronic switch, wherein the primary side full bridge circuit is configured to generate a first voltage, and wherein configurations of the first electronic switch, the second electronic switch, the third electronic switch, and the fourth electronic switch define an operating cycle pattern, the two-level DC-DC converter further including a secondary side power stage circuit including a second plurality of electronic components, the secondary side power stage circuit configured to generate a second voltage, a transformer coupled between the primary side full bridge circuit and the secondary side power stage circuit, the control circuit comprising: a PI controller and a duty cycle control circuit configured for: controlling duty cycles of the first electronic switch and the second electronic switch of the first leg such that a duty cycle of one of the first electronic switch and the second electronic switch is greater than 50%, wherein the first electronic switch and the second electronic switch have complementary duty cycles; controlling duty cycles of the third electronic switch and the fourth electronic switch of the second leg, such that a duty cycle of one of the third electronic switch and the fourth electronic switch is greater than 50%, wherein the third electronic switch and the fourth electronic switch have complementary duty cycles; and after N cycles of the operating cycle pattern: inverting the duty cycles of the first electronic switch and the second electronic switch of the first leg; and inverting the duty cycles of the third electronic switch and the fourth electronic switch of the second leg.

In some aspects, this disclosure is directed to a method of operating a two-level DC-DC converter having a primary side full bridge circuit and a secondary side power stage circuit, the primary side full bridge circuit including a first leg having a first electronic switch and a second electronic switch and a second leg having a third electronic switch and a fourth electronic switch, the method comprising: controlling duty cycles of the first electronic switch and the second electronic switch of the first leg such that a duty cycle of one of the first electronic switch and the second electronic switch is greater than 50%, wherein the first electronic switch and the second electronic switch have complementary duty cycles; controlling duty cycles of the third electronic switch and the fourth electronic switch of the second leg, such that a duty cycle of one of the third electronic switch and the fourth electronic switch is greater than 50%, wherein the third electronic switch and the fourth electronic switch have complementary duty cycles, wherein configurations of the first electronic switch, the second electronic switch, the third electronic switch, and the fourth electronic switch define an operating cycle pattern for the primary side full bridge circuit; and after N cycles of the operating cycle pattern: inverting the duty cycles of the first electronic switch and the second electronic switch of the first leg; and inverting the duty cycles of the third electronic switch and the fourth electronic switch of the second leg.

### BRIEF DESCRIPTION OF THE DRAWINGS

In the drawings, which are not necessarily drawn to scale, like numerals may describe similar components in different views. The drawings illustrate generally, by way of example, but not by way of limitation, various embodiments discussed in the present document.

FIG. 1 is a perspective view of an example of an electric machine that may implement various DC converter techniques of this disclosure.

FIG. 2 is a diagrammatic view of an example of an electric powertrain using the DC/DC converter of this disclosure.

FIG. 3 is a schematic illustration of an example of a two-level DC-DC converter that may implement various techniques of this disclosure.

FIG. 4 is a table depicting an example of an operating cycle pattern over multiple operating cycles that may be used to control the switches in a primary side full bridge circuit of a two-level DC-DC converter, in accordance with this disclosure.

FIG. 5 is a schematic illustration of a two-level DC-DC converter that may implement various techniques of this disclosure.

FIG. 6 is a table depicting another example of an operating cycle pattern over multiple operating cycles that may be used to control the switches in a primary side full bridge circuit of a two-level DC-DC converter, in accordance with this disclosure.

FIG. 7 is a block diagram of an example of a control circuit that may implement various techniques of this disclosure.

FIG. 8 is a flow diagram of an example of a method of operating a two-level DC-DC converter having a primary side full bridge circuit and a secondary side power stage circuit, the primary side full bridge circuit including a first leg having a first electronic switch and a second electronic switch and a second leg having a third electronic switch and a fourth electronic switch.

### DETAILED DESCRIPTION

The present inventors have recognized that two-level single active bridge (SAB) and dual active bridge (DAB) converters have inherent unequal loss distribution between switches in the top half and the bottom half of the H bridge. This imbalance in losses between the two halves results in the switches of one of the halves reaching their rated temperature limit sooner than the switches of the other half. Given that power semiconductor switches are the major components in SAB and DAB converter topologies, the thermal limitations caused by the imbalances in the two halves may lead to lower a power density of the overall converter.

This disclosure describes techniques that address the unequal loss distribution between switches in the top half and the bottom half of the primary side full bridge circuit of the H bridge of two-level SAB and DAB converters, The techniques involve dynamically controlling the duty cycles of power switches in the top and the bottom switches of the primary side full bridge circuit and, as a result, balancing their temperature. In particular, the duty cycles of the switches may be “toggled” after N cycles of an operating cycle pattern so as to invert the duty cycles of the complementary switches. Inverting the duty cycles of the complementary switches reverses (or “toggles”) the duty cycles between the complementary switch pairs. By implementing this approach, the techniques achieve a balanced loss distribution between the two halves, thereby facilitating higher power density operation.

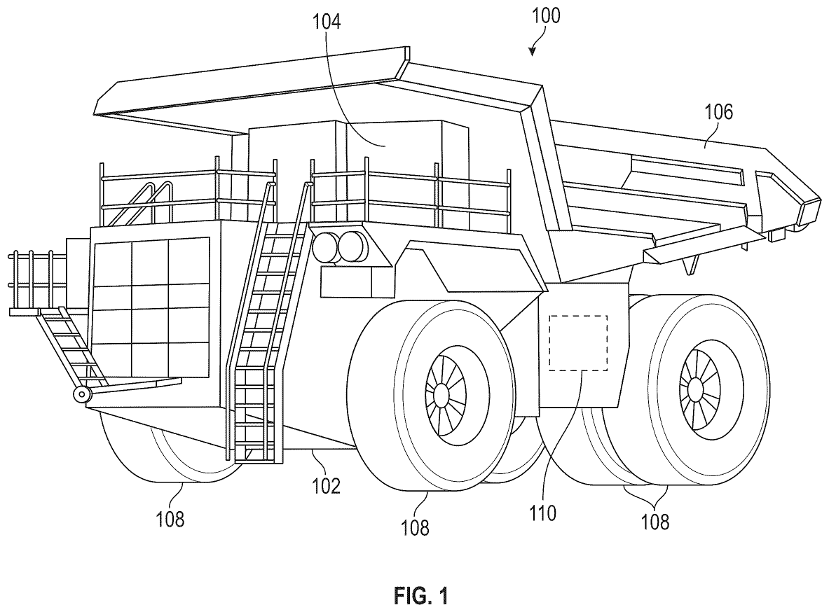

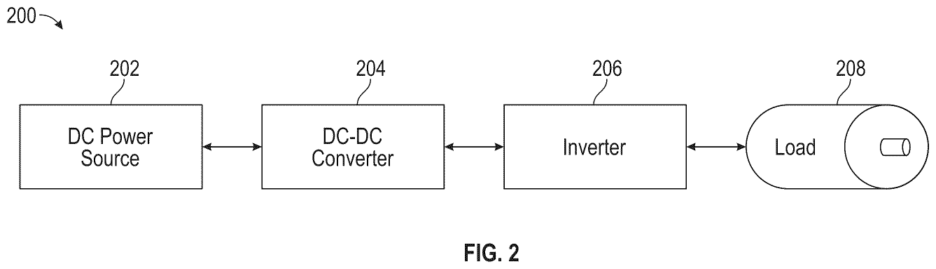

FIG. 1 is a perspective view of an example of an electric machine that may implement various DC converter techniques of this disclosure. A non-limiting example of machine 100 is shown in FIG. 1. The machine 100 may be any stationary or mobile machine powered, at least partially, by batteries, as will be described below with reference to FIG. 2. The machine 100 may be a mining truck, as depicted, or may alternatively embody an on-highway or off-highway machine or any other vehicle that is configured to be propelled.

In some examples, the machine 100 includes a frame 102 supporting at least an operator control station 104 and a dump body 106. Traction components 108 may form part of a wheel-drive system, a track-drive system, or any other type of drive system configured to propel the machine 100. Examples of traction components include wheels, track(s), or a combination of wheels and one or more tracks. The traction components 108 may be powered by a drive system, discussed below, supported by the frame 102.

The machine 100 also includes an electrical architecture 110. The electrical architecture 110 may include a DC power source, including but not limited to a battery module, that may supply power to, among other things, an electric motor. The electric motor may supply rotational power to one or more systems, such as a system configured to operate various hydraulics of the dump body 106. The techniques of this disclosure are applicable generally to industrial vehicles including, but not limited to, continuous miners, feeder breakers, roof bolters, utility vehicles for mining, underground mining loaders, underground articulated trucks, or any other vehicle used for industrial purposes, such as hauling, excavating, drilling, loading, dumping, compacting, etc. Further, the techniques of this disclosure, while especially suited to use in battery-powered vehicles, also could be used in hybrid-powered vehicles, and internal-combustion-powered vehicles.

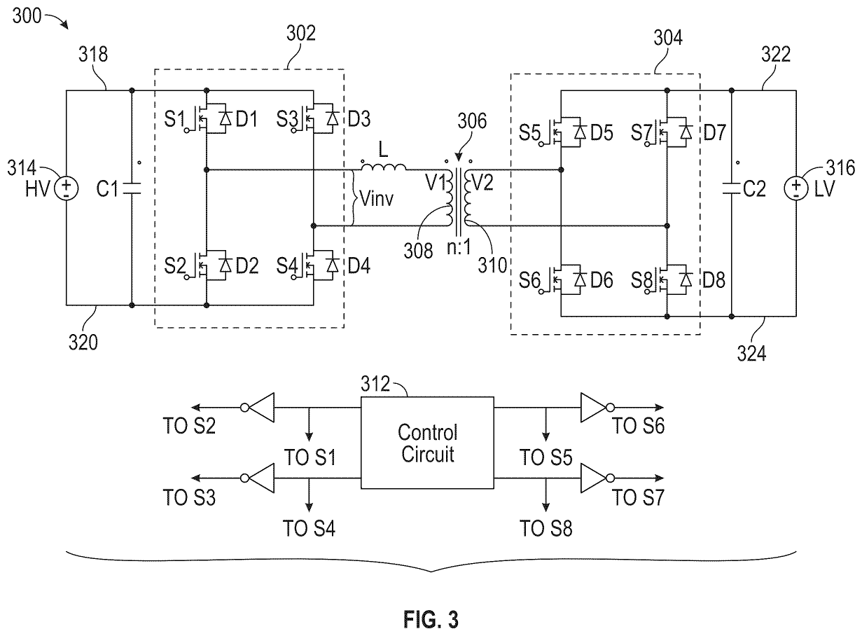

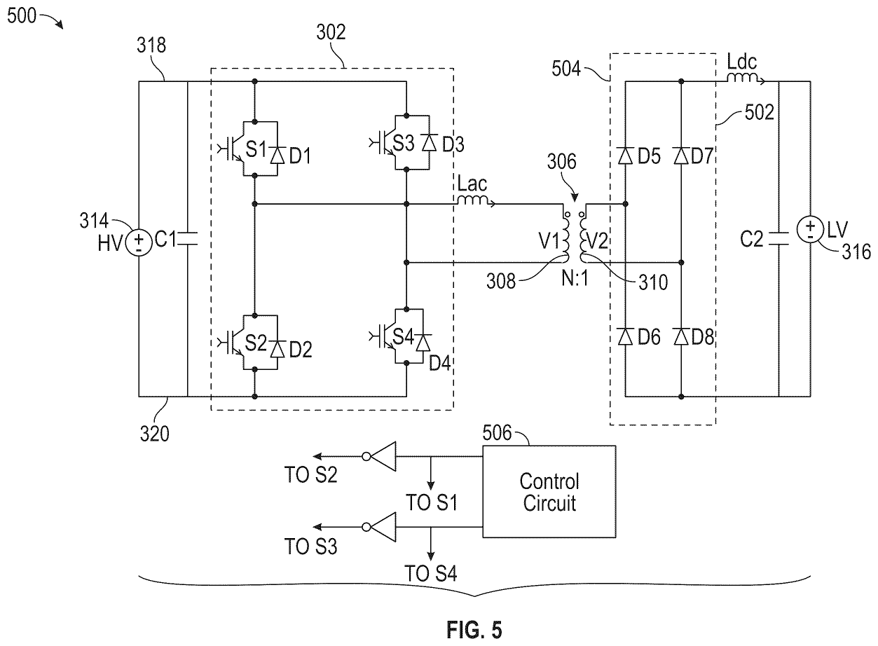

FIG. 2 is a diagrammatic view of an example of an electric powertrain using the DC/DC converter of this disclosure. The powertrain 200 may be used in combination with an electric machine, such as the machine 100 of FIG. 1. In the examples shown, the powertrain 200 includes a DC power source 202, such as one or more battery modules that each include one or more battery cells. The DC power source 202 is coupled to a two-level DC-DC converter 204 configured to implement various techniques of this disclosure, such as the DAB converter 300 of FIG. 3 and/or the two-level single active bridge (SAB) 500 of FIG. 5.

The DC-DC converter 204 is coupled to an inverter 206, which generates an AC voltage from the output of the DC-DC converter 204. An electrically drivable load 208, such as a motor of an electric machine is coupled to the inverter 206.

FIG. 3 is a schematic illustration of an example of a two-level DC-DC converter 300 that may implement various techniques of this disclosure. The two-level DC-DC converter 300 may be used with the machine of FIG. 1.

The two-level DC-DC converter 300 includes a two-level primary side full bridge circuit 302 and a secondary side power stage circuit 304. In particular, the secondary side power stage circuit 304 includes a secondary side full bridge circuit and, as such, the two-level DC-DC converter 300 is a dual-active bridge circuit. In the example shown, the secondary side power stage circuit 304 is a two-level circuit.

The primary side full bridge circuit 302 includes a plurality of electronic components, including a plurality of electronic switches S1-S4 paired with corresponding freewheeling diodes D1-D4. The switches S1 and S3 are coupled with a positive voltage rail 318 and the switches S2 and S4 are coupled with a negative voltage rail 320.

The secondary side power stage circuit 304 includes a plurality of electronic components, including a plurality of electronic switches S5-S8 paired with corresponding freewheeling diodes D5-D8. The switches S5 and S7 are coupled with a positive voltage rail 322 and the switches S6 and S8 are coupled with a negative voltage rail 324.

The two-level DC-DC converter 300 includes a transformer 306 coupled between the primary side full bridge circuit 302 and the secondary side power stage circuit 304. The transformer 306 includes a turns ratio of n:1. The two-level DC-DC converter 300 includes an inductor L coupled between the primary side full bridge circuit 302 and a primary winding 308 of the transformer 306. In some examples, the two-level DC-DC converter 300 includes an inductor Lac and an inductor Ldc, as shown in FIG. 5.

The primary side full bridge circuit 302 is configured to generate a voltage V1 at the primary winding 308 of the transformer 306 and the secondary side power stage circuit 304 is configured to generate a voltage V2 at a secondary winding 310 of the transformer 306. A control circuit 312 is configured to, among other things, generate control signals to control operation of the switches S1-S8 so that the primary side full bridge circuit 302 and the secondary side power stage circuit 304 may generate the voltages V1, V2, respectively.

The primary side full bridge circuit 302 is coupled to a first voltage source 314 HV and a capacitor C1. In some examples, the first voltage source 314 is an external power source, such as a trolley system that provides power to electrical architecture via overhead lines or other infrastructure. The first voltage source 314 may provide a voltage greater than 2500V, such as 2700V-2800V. The secondary side power stage circuit 304 is coupled to a second voltage source 316 LV and a capacitor C2. In some examples, the second voltage source 316 is a battery.

The sets of electronic switches (S1, S2), (S3, S4), (S5, S6), and (S7, S8) are complementary pairs, respectively. Thus, if S1 is ON then S2 will be OFF and if S1 is OFF then S2 will be ON, for example. Each set of electronic switches is referred to as a leg, with the switches S1 and S2 forming a first leg and the switches S3 and S4 forming a second leg.

The control circuit 312 is configured for controlling the operation of the electronic switches S1-S4 of the primary side full bridge circuit 302 so as to define an operating cycle pattern of active state, zero state, active state, zero state, and so forth. When the switches are in an active state, they are being actively controlled to conduct and allow current to flow through the circuit. In some examples, the control circuit 312 achieves this through pulse-width modulation (PWM) techniques. The active state includes both an active positive state and an active negative state. In the active positive state, the control circuit 312 turns ON both the switch S1 and the switch S4 so as to couple the primary winding 308 of the transformer 306, via the inductor L, to the positive rail. In the active negative state, the control circuit 312 turns ON the switch S2 and the switch S3 so as to couple the primary winding 308, via the inductor L, to the negative rail.

In the active positive state, the switches on the primary side are configured in such a way that energy is transferred from the primary side (input side) to the secondary side (output side) with a positive power flow direction. In the active negative state, the switches are configured to allow energy transfer in the opposite direction, which means power is flowing from the secondary side back to the primary side, or the phase shift is such that the power flow direction is reversed.

Between the active positive state and the active negative state, the operating cycle pattern includes a zero state, or zero voltage state. In the zero state, the control circuit 312 turns ON one of the switches (with the other switches in the primary side full bridge circuit 302 turned OFF) and current freewheels through a diode. For example, the control circuit 312 turns ON the switch S3, turns OFF the switches S1, S2, and S4, and current freewheels through the diode D1. There is no net power transfer between the primary and secondary sides during a zero state.

The present inventors have recognized that two-level single active bridge (SAB) and dual active bridge (DAB) converters have inherent unequal loss distribution between switches in the top half (S1, S3) and the bottom half (S2, S4) of the H bridge. This imbalance in losses between the top and the bottom halves results in the switches of the top half (or bottom half) reaching their rated temperature limit sooner than the switches of the bottom half (or top half). Given that power semiconductor switches are the major components in SAB and DAB converter topologies, the thermal limitations caused by the imbalances in the two halves may lead to lower power density of the overall converter.

This disclosure describes techniques that address the unequal loss distribution between switches in the top and the bottom halves of two-level SAB and DAB converters, where switches in the top or the bottom halves reach their temperature limit sooner due to imbalanced losses. The techniques involve dynamically controlling the duty cycles of power switches in both halves simultaneously to balance out the losses and temperatures amongst the switches. By implementing this approach, the techniques achieve a balanced loss distribution between the two halves, thereby facilitating higher power density operation.

Existing approaches control the output voltage and power of two-level SAB and DAB converters by controlling the phase shift between the two legs of the H bridge. In these existing approaches, the duty cycles of the electronic switches (S1, S2) and (S3, S4) are fixed at 50% and the phase shift between the switches of the two legs of the H bridge controls the power flow.

The present inventors have recognized the desirability of balancing the use of the top switches (S1, S3) of the primary side full bridge circuit 302 with the bottom switches (S2, S4) so as to balance the temperature amongst these switches. Using various techniques of this disclosure, power flow is controlled by adjusting the duty cycles of the switches and by fixing the phase shift between the switches of the two legs of the H bridge at 180 degrees. To balance the use of the top and the bottom switches of the primary side full bridge circuit 302 and, as a result, balance their temperature, the duty cycles of the switches may be “toggled” after N cycles of an operating cycle pattern so as to invert the duty cycles of the complementary switches. Inverting the duty cycles of the complementary switches reverses (or “toggles”) the duty cycles between the complementary switch pairs. This toggling maintains the complementary nature of each switch pair forming a leg (their duty cycles still sum to 100%), but reverses which switch in each pair has the higher duty cycle. It is essentially a mirror image of the original configuration in terms of duty cycles.

As a non-limiting example, assume that switch S1 of the first leg has a duty cycle of 60%, complementary switch S2 of the first leg has a duty cycle of 40%, switch S3 of the second leg has a duty cycle of 60%, and complementary switch S4 of the second leg has a duty cycle of 40%. Without any balancing, switches S1 and S3, e.g., the top switches of the two legs, will have a higher temperature than the switches S2 and S4, e.g., the bottom switches, due to their greater duty cycle.

Using the techniques of this disclosure and in order to balance the temperature between the top switches (S1, S3) and the bottom switches (S2, S4) of the primary side full bridge circuit 302, the duty cycles of the switches may “toggle” after N cycles (where N is greater than or equal to 1) of an operating cycle pattern such that the duty cycles of the top switches and bottom switches are inverted. Continuing the non-limiting example from above and after N cycles of an operating cycle pattern, the duty cycles of the switches may be inverted such that the new duty cycle of switch S1 of the first leg is 40%, complementary switch S2 of the first leg has a new duty cycle of 60%, switch S3 of the second leg has a new duty cycle of 40%, and complementary switch S4 of the second leg has a new duty cycle of 60%. Then, after another N cycles of the operating cycle pattern, the duty cycles of the switches may be inverted again such that the new duty cycle of switch S1 of the first leg is 60%, complementary switch S2 of the first leg has a new duty cycle of 40%, switch S3 of the second leg has a new duty cycle of 60%, and complementary switch S4 of the second leg has a new duty cycle of 40%.

The duty cycle ratios of 60/40 (and 40/60) within the two legs of the H bridge assume that the load condition, for example, has remained the same over the multiple N cycles. Otherwise, the particular duty cycle ratios may change to account for the changing load conditions even as the swapping between the top and bottom switches to balance the temperature continues. For example, assuming the load condition has changed and continuing the non-limiting example from above, after N cycles of an operating cycle pattern the duty cycles of the switches may be inverted such that the new duty cycle of switch S1 of the first leg is 45%, complementary switch S2 of the first leg has a new duty cycle of 55%, switch S3 of the second leg has a new duty cycle of 45%, and complementary switch S4 of the second leg has a new duty cycle of 55%. Even with this change in duty cycle ratios of 45/55 (and 55/45) due to the changing load conditions, the duty cycles of the switches may be inverted after N cycles of an operating cycle pattern such that the duty cycles of the top switches and bottom switches are swapped.

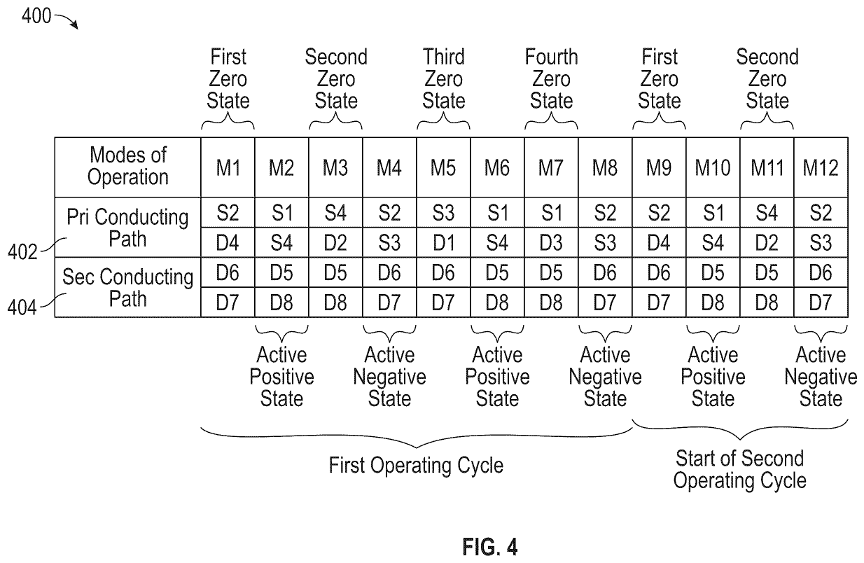

FIG. 4 is a table depicting an example of an operating cycle pattern over multiple operating cycles that may be used to control the switches in a primary side full bridge circuit of a two-level DC-DC converter, in accordance with this disclosure. In particular, the table 400 depicts modes of operation M1-M12 that the control circuit 312 of FIG. 3 uses for controlling the operation of the switches S1-S8 of the two-level dual active bridge circuit of FIG. 3.

Each mode of operation includes switch configurations for the primary side conducting path 402 and the secondary side conducting path 404. The switches listed in each mode of operation in the table 400 are the switches that are ON in that mode, with all other switches OFF in that mode of operation. For example, in the primary side conducting path 402 in mode of operation M1, the switch S2 is in an ON state and diode D4 is conducting, and the switches S1, S3, and S4 of the primary side full bridge circuit 302 of FIG. 3 are in an OFF state.

Configurations of the switches S1-S4 of the primary side conducting path 402 define an operating cycle pattern that includes four zero states, an active positive state, and an active negative state. A cycle is complete when the four zero states, the active positive state, and the active negative state have been completed. For example, FIG. 4 depicts a first operating cycle that includes modes M1-M8. A second operating cycle begins at mode M9 but is not complete in FIG. 4.

Referring only to the primary side conducting path 402, the mode M1 is a first zero state, the mode M2 is an active positive state, the mode M3 is a second zero state, the mode M4 is an active negative state, the mode M5 is a third zero state, the mode M6 is an active positive state, the mode M7 is a fourth zero state, the mode M8 is an active negative state, the mode M9 is a first zero state, the mode M10 is an active positive state, the mode M11 is a second zero state, the mode M12 is an active negative state, and so forth. The secondary side conducting path 404 will not be discussed further and is only presented in the table 400 for completeness.

An active positive state is where both switches S1 and S4 are in an ON state and both switches S2 and S3 are in an OFF state. An active negative state is where both switches S2 and S3 are in an ON state and both switches S1 and S4 are in an OFF state.

In the zero states, one of the switches in either the top half or bottom half of the primary side full bridge circuit 302 is in an ON state while the remaining three switches of the primary side full bridge circuit 302 are in an OFF state. For example, as shown in FIG. 4, the first zero state in mode M1 depicts switch S2 in an ON state and switches S1, S3, and S4 in an OFF state. In the second zero state, switch S4 is in an ON state and the switches S1-S3 are in an OFF state. In the third zero state, switch S3 is in an ON state and the switches S1, S2, and S4 are in an OFF state. In the fourth zero state, switch S1 is in an ON state and the switches S2-S4 are in an OFF state.

The operation of the switches used in the zero states is controlled so as to balance a number of times the first electronic switch, the second electronic switch, the third electronic switch, and the fourth electronic switch are used during the zero states of an operating cycle. For example, mode M1 (first zero state) uses the switch S2, mode M3 (second zero state) uses the switch S4, mode M5 (third zero state) uses the switch S3, and mode M7 (fourth zero state) uses the switch S1. In this manner, over an operating cycle, each of the switches S1-S4 is used only once during a corresponding zero state mode. By controlling the operation of the switches S1-S4 of the primary side full bridge circuit 302, no one switch is overused. The control circuit controls the operation of the electronic switches over the course of the operating cycles so as to balance the use of the switches S1-S4, which reduces the loss distribution between the two legs of the primary side full bridge circuit 302 of FIG. 3.

It should be noted that the switching pattern shown in FIG. 4 is an example of a switching pattern. In the first zero state and the second zero state, one of the second electronic switch S2 and the fourth electronic switch S4 is in an ON state and the other of the second electronic switch S2 and the fourth electronic switch S4 in an OFF state, and both the first electronic switch S1 and the third electronic switch S3 are in the OFF state. In the third zero state and the fourth zero state, one of the first electronic switch S1 and the third electronic switch S3 is in an ON state and the other of the first electronic switch S1 and the third electronic switch S3 is in an OFF state, and both the second electronic switch S2 and the fourth electronic switch S4 are in the OFF state. In an equivalent switching pattern, the first zero state and the second zero state may be interchanged. In another equivalent switching pattern, the third zero state and the fourth zero state may be interchanged. As mentioned above, the techniques of this disclosure are directed to controlling the operation of the switches such that over an operating cycle, each of the switches S1-S4 is used only once during a corresponding zero state mode.

FIG. 5 is a schematic illustration of a two-level DC-DC converter 500 that may implement various techniques of this disclosure. The two-level DC-DC converter 500 may be used with the machine of FIG. 1.

The two-level DC-DC converter 500 includes a two-level primary side full bridge circuit 302 and a secondary side power stage circuit 504, each having a plurality of electronic components. The primary side full bridge circuit 302 is similar to the primary side full bridge circuit 302 of FIG. 3 and, for conciseness, will not be described in detail again. The secondary side power stage circuit 504 includes a plurality of diodes D5-D8 arranged as a rectifier circuit. The two-level DC-DC converter 500 is an example of a phase-shifted full bridge circuit.

The primary side full bridge circuit 302 includes a plurality of electronic components, including a plurality of electronic switches S1-S4 paired with corresponding freewheeling diodes D1-D4. The switches S1 and S3 are coupled with a positive voltage rail 318 and the switches S2 and S4 are coupled with a negative voltage rail 320.

The two-level DC-DC converter 500 includes a transformer 306 coupled between the primary side full bridge circuit 302 and the secondary side power stage circuit 504. The transformer 306 includes a turns ratio of n:1. The two-level DC-DC converter 500 includes an inductor Lac coupled between the primary side full bridge circuit 302 and a primary winding 308 of the transformer 306. The two-level DC-DC converter 500 includes an inductor Ldc coupled between the secondary side power stage circuit 504 and the the second voltage source 316.

The primary side full bridge circuit 302 is configured to generate a voltage V1 at the primary winding 308 of the transformer 306 and the secondary side power stage circuit 504 is configured to generate a voltage V2 at a secondary winding 310 of the transformer 306. A control circuit 506 is configured to, among other things, generate control signals to control operation of the switches S1-S4 so that the primary side full bridge circuit 302 and the secondary side power stage circuit 504 may generate the voltages V1, V2, respectively.

The primary side full bridge circuit 302 is coupled to a first voltage source 314 HV and a capacitor C1. In some examples, the first voltage source 314 is an external power source, such as a trolley system that provides power to electrical architecture via overhead lines or other infrastructure. The first voltage source 314 may provide a voltage greater than 2500V, such as 2700V-2800V. The secondary side power stage circuit 304 is coupled to a second voltage source 316 LV and a capacitor C2. In some examples, the second voltage source 316 is a battery.

The sets of electronic switches (S1, S2) and (S4, S3) are complementary pairs, such as with each switch operating at 50% duty cycle, respectively. Thus, if S1 is ON then S2 will be OFF and if S1 is OFF then S2 will be ON, for example. Each set of electronic switches is referred to as a leg, with the switches S1 and S2 forming a first leg and the switches S3 and S4 forming a second leg.

The control circuit 506 is configured for controlling the operation of the electronic switches S1-S4 of the primary side full bridge circuit 302 so as to define an operating cycle pattern of active state, zero state, active state, zero state, and so forth. These states were described in detail above with respect to FIG. 3 and FIG. 4 and, for conciseness, will not be described in detail again.

The ON/OFF configurations of the switches S1-S4 define an operating cycle pattern of an active positive state, a first zero state, an active negative state, and a second zero state over one operating cycle for the primary side full bridge circuit 302. A control circuit, such as the control circuit 506, controls the switches so as to balance a number of times the first electronic switch, the second electronic switch, the third electronic switch, and the fourth electronic switch are used during the zero states of an operating cycle, as described in more detail below.

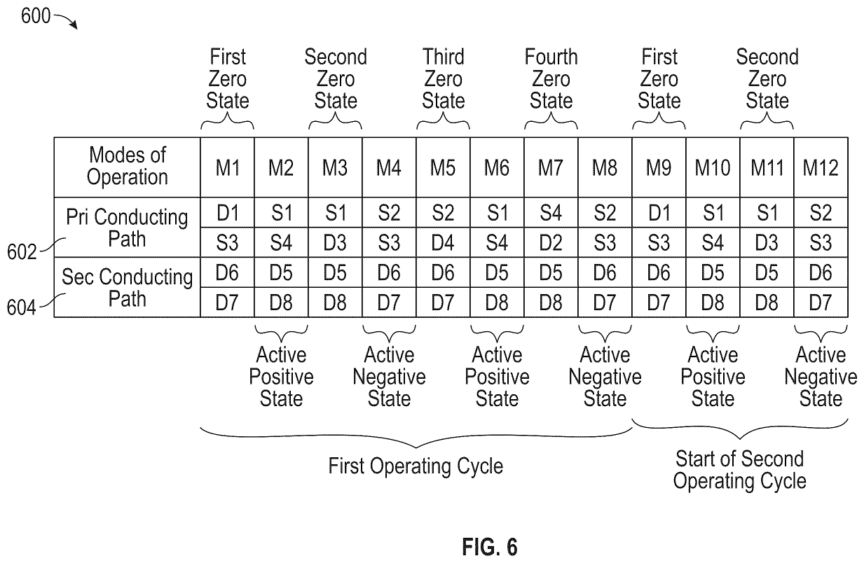

FIG. 6 is a table depicting another example of an operating cycle pattern over multiple operating cycles that may be used to control the switches in a primary side full bridge circuit of a two-level DC-DC converter, in accordance with this disclosure. The table 600 depicts modes of operation M1-M12.

Each mode of operation includes switch configurations for the primary side conducting path 602 and the secondary side conducting path 604. The switches listed in each mode of operation in the table 600 are the switches that are ON in that mode, with all other switches OFF in that mode of operation. For example, in the primary side conducting path 602 in mode M1, the switch S3 is in an ON state and diode D1 is conducting, with the switches S1, S2, and S4 of the primary side full bridge circuit 302 of FIG. 5 are in OFF state.

Configurations of the switches S1-S4 of the primary side conducting path 402 define an operating cycle pattern that includes four zero states, an active positive state, and an active negative state. A cycle is complete when the four zero states, the active positive state, and the active negative state have been completed. For example, FIG. 6 depicts a first operating cycle that includes modes M1-M8. A second operating cycle begins at mode M9 but is not complete in FIG. 6.

Referring only to the primary side conducting path 602, the mode M1 is a first zero state, the mode M2 is an active positive state, the mode M3 is a second zero state, the mode M4 is an active negative state, the mode M5 is a third zero state, the mode M6 is an active positive state, the mode M7 is a fourth zero state, the mode M8 is an active negative state, the mode M9 is a first zero state, the mode M10 is an active positive state, the mode M11 is a second zero state, the mode M12 is an active negative state, and so forth. The secondary side conducting path 604 will not be discussed further and is only presented in the table 600 for completeness.

An active positive state is where both switches S1 and S4 are in an ON state and both switches S2 and S3 are in an OFF state. An active negative state is where both switches S2 and S3 are in an ON state and both switches S1 and S4 are in an OFF state.

In the zero states, one of the switches in either the top half or bottom half of the primary side full bridge circuit 302 of FIG. 5 is in an ON state while the remaining three switches of the primary side full bridge circuit 302 are in an OFF state. For example, as shown in FIG. 6, the first zero state in mode M1 depicts switch S3 in an ON state and switches S1, S2, and S4 in an OFF state. In the second zero state, switch S1 is in an ON state and the switches S2-S4 are in an OFF state. In the third zero state, switch S2 is in an ON state and the switches S1, S3, and S4 are in an OFF state. In the fourth zero state, switch S4 is in an ON state and the switches S1-S3 are in an OFF state.

The control circuit 506 of FIG. 5 controls the operation of the switches used in the zero states so as to balance a number of times the first electronic switch, the second electronic switch, the third electronic switch, and the fourth electronic switch are used during the zero states of an operating cycle. For example, mode M1 (first zero state) uses the switch S3, mode M3 (second zero state) uses the switch S1, mode M5 (third zero state) uses the switch S2, and mode M7 (fourth zero state) uses the switch S4. In this manner, over an operating cycle, each of the switches S1-S4 is used only once during a corresponding zero state mode. By controlling the operation of the switches S1-S4 of the primary side full bridge circuit 302 of FIG. 5, no one switch is overused. The control circuit controls the operation of the electronic switches over the course of the operating cycles so as to balance the use of the switches S1-S4 over an operating cycle, which reduces the loss distribution between the two legs of the primary side full bridge circuit 302 of FIG. 5.

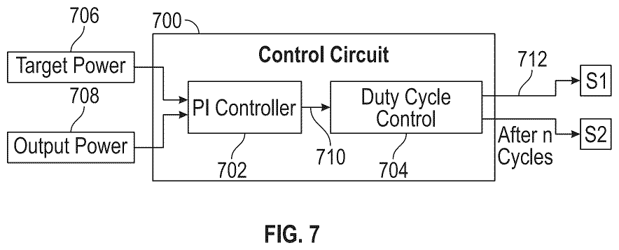

FIG. 7 is a block diagram of an example of a control circuit 700 that may implement various techniques of this disclosure. The control circuit 700 is an example of the control circuit 506 of FIG. 5. The control circuit 312 is similarly configured, except that the inputs to the control circuit 312 include target voltage and output voltage rather than target power and output power.

In the example shown, the control circuit 700 includes a Proportional Integral (PI) controller, namely PI controller 702, coupled with a duty cycle control circuit 704. The target power 706 and the output power 708 are input signals to the PI controller 702. The PI controller 702 determined an error by subtracting the output power 708 from the target power 706. The PI controller 702 then adjusts its output based on this error using proportional and integral terms, generating a control signal 710 that is applied to the-duty cycle control circuit 704 and used to adjust the duty cycle of the switches in the first leg and the second leg, such as the switches S1 and S2 in the first leg.

The duty cycle control circuit 704 receives the control signal 710 from the PI controller 702 and generates a signal 712 representing a duty cycle, which determines the ON/OFF timing between the complementary switches in each leg of the primary side full bridge circuit 302 of the two-level DC-DC converter. The duty cycle is used to generate gate signals to control the switches in the two-level DC-DC converter, such as the switches S1 and S2 in the first leg as shown.

As described above, the switches S1-S4 of the primary side full bridge circuit 302 are controlled in such a way that there are active states and zero states. The active states refer to the periods when power is actively transferred between the primary and secondary sides of the converter, while the zero states refer to the periods when no power is being transferred. The control circuit 700 adjusts the duty cycle between the first leg and the second leg to regulate the power transfer.

The duty cycle control circuit 704 balances the use of the top switches (S1, S3) of the primary side full bridge circuit 302 of FIG. 3 and FIG. 5 with the bottom switches (S2, S4) so as to balance the temperature between these switches. As mentioned above, to balance the use of the top and bottom switches of the primary side full bridge circuit 302 and, as a result, balance their temperature, the duty cycles of the switches may be “toggled” after N cycles of an operating cycle pattern so as to invert the duty cycles of the complementary switches. Inverting the duty cycles of the complementary switches reverses (or “toggles”) the duty cycles between the complementary switch pairs. This toggling maintains the complementary nature of each switch pair (their duty cycles still sum to 100%), but reverses which switch in each pair has the higher duty cycle. It is essentially a mirror image of the original configuration in terms of duty cycles.

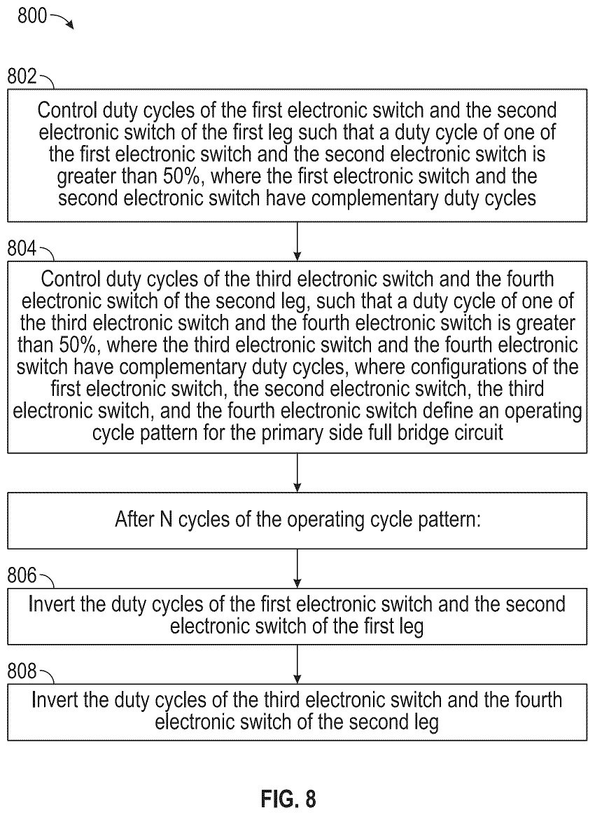

FIG. 8 is a flow diagram of an example of a method 800 of operating a two-level DC-DC converter having a primary side full bridge circuit and a secondary side power stage circuit, the primary side full bridge circuit including a first leg having a first electronic switch and a second electronic switch and a second leg having a third electronic switch and a fourth electronic switch.

At block 802, the method 800 includes controlling duty cycles of the first electronic switch and the second electronic switch of the first leg such that a duty cycle of one of the first electronic switch and the second electronic switch is greater than 50%, wherein the first electronic switch and the second electronic switch have complementary duty cycles.

At block 804, the method 800 includes controlling duty cycles of the third electronic switch and the fourth electronic switch of the second leg, such that a duty cycle of one of the third electronic switch and the fourth electronic switch is greater than 50%, wherein the third electronic switch and the fourth electronic switch have complementary duty cycles, wherein configurations of the first electronic switch, the second electronic switch, the third electronic switch, and the fourth electronic switch define an operating cycle pattern for the primary side full bridge circuit.

At block 806 and after N cycles (where N is greater than or equal to 1) of the operating cycle pattern, the method 800 includes inverting the duty cycles of the first electronic switch and the second electronic switch of the first leg.

At block 808, the method 800 includes inverting the duty cycles of the third electronic switch and the fourth electronic switch of the second leg.

### Various Notes

Each of the non-limiting claims or examples described herein may stand on its own, or may be combined in various permutations or combinations with one or more of the other examples.

The above detailed description includes references to the accompanying drawings, which form a part of the detailed description. The drawings show, by way of illustration, specific embodiments in which the invention may be practiced. These embodiments are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more claims thereof), either with respect to a particular example (or one or more claims thereof), or with respect to other examples (or one or more claims thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein may be machine or computer-implemented at least in part. Some examples may include a computer-readable medium or machine-readable medium encoded with instructions operable to configure an electronic device to perform methods as described in the above examples. An implementation of such methods may include code, such as microcode, assembly language code, a higher-level language code, or the like. Such code may include computer readable instructions for performing various methods. The code may form portions of computer program products. Further, in an example, the code may be tangibly stored on one or more volatile, non-transitory, or non-volatile tangible computer-readable media, such as during execution or at other times. Examples of these tangible computer-readable media may include, but are not limited to, hard disks, removable magnetic disks, removable optical disks (e.g., compact discs and digital video discs), magnetic cassettes, memory cards or sticks, random access memories (RAMs), read only memories (ROMs), and the like.

The above description is intended to be illustrative, and not restrictive. For example, the above-described examples (or one or more claims thereof) may be used in combination with each other. Other embodiments may be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments may be combined with each other in various combinations or permutations. The scope of the invention should be determined with reference to the appended claims, along with the full scope of equivalents to which such claims are entitled.

What is claimed is:

1. A two-level DC-DC converter comprising:
a primary side full bridge circuit including:
a first leg having a first electronic switch and a second electronic switch; and
a second leg having a third electronic switch and a fourth electronic switch, wherein the third electronic switch and the fourth electronic switch have complementary switching operations,
wherein configurations of the first electronic switch, the second electronic switch, the third electronic switch, and the fourth electronic switch define an operating cycle pattern for the primary side full bridge circuit, and
wherein the primary side full bridge circuit is configured to generate a first voltage; and
a secondary side power stage circuit including a second plurality of electronic components, the secondary side power stage circuit configured to generate a second voltage;
a transformer coupled between the primary side full bridge circuit and the secondary side power stage circuit; and
a control circuit configured for:
controlling duty cycles of the first electronic switch and the second electronic switch of the first leg such that a duty cycle of one of the first electronic switch and the second electronic switch is greater than 50%, wherein the first electronic switch and the second electronic switch have complementary duty cycles;
controlling duty cycles of the third electronic switch and the fourth electronic switch of the second leg, such that a duty cycle of one of the third electronic switch and the fourth electronic switch is greater than 50%, wherein the third electronic switch and the fourth electronic switch have complementary duty cycles; and
after N cycles of the operating cycle pattern:
inverting the duty cycles of the first electronic switch and the second electronic switch of the first leg; and
inverting the duty cycles of the third electronic switch and the fourth electronic switch of the second leg.

2. The two-level DC-DC converter of claim 1, wherein the control circuit is configured for:
maintaining a phase angle of 180 degrees between an electronic switch of the first leg and an electronic switch of the second leg.

3. The two-level DC-DC converter of claim 1, wherein the secondary side power stage circuit includes a secondary side full bridge circuit, and wherein the two-level DC-DC converter is a dual-active bridge circuit.

4. The two-level DC-DC converter of claim 3, wherein the secondary side full bridge circuit is a two-level circuit.

5. The two-level DC-DC converter of claim 1, wherein the secondary side power stage circuit includes a rectifier circuit, and wherein the two-level DC-DC converter is a single active full bridge circuit.

6. The two-level DC-DC converter of claim 1, wherein the control circuit is configured for:
controlling an operation of the first electronic switch, the second electronic switch, the third electronic switch, and the fourth electronic switch to use a first zero state, a second zero state, a third zero state, and a fourth zero state within the operating cycle pattern so as to balance a number of times the first electronic switch, the second electronic switch, the third electronic switch, and the fourth electronic switch are used.

7. The two-level DC-DC converter of claim 6, wherein the control circuit configured for controlling the operation of the first electronic switch, the second electronic switch, the third electronic switch, and the fourth electronic switch to use a first zero state, a second zero state, a third zero state, and a fourth zero state within the operating cycle pattern so as to balance the number of times the first electronic switch, the second electronic switch, the third electronic switch, and the fourth electronic switch are used is configured for:
controlling the operation of the first electronic switch, the second electronic switch, the third electronic switch, and the fourth electronic switch to generate the operating cycle pattern of:
the first zero state, an active positive state, the second zero state, an active negative state, the third zero state, the active positive state, the fourth zero state, and the active negative state.

8. The two-level DC-DC converter of claim 6, wherein the first electronic switch and the third electronic switch are coupled with a positive voltage rail, wherein the second electronic switch and the fourth electronic switch are coupled with a negative voltage rail,
wherein the first zero state includes:
one of the second electronic switch and the fourth electronic switch in an ON state and the other of the second electronic switch and the fourth electronic switch in an OFF state, and
both the first electronic switch and the third electronic switch in the OFF state, and
wherein the second zero state includes:
one of the first electronic switch and the third electronic switch in an ON state and the other of the first electronic switch and the third electronic switch in an OFF state, and
both the second electronic switch and the fourth electronic switch in the OFF state.

9. A method of operating a two-level DC-DC converter having a primary side full bridge circuit and a secondary side power stage circuit, the primary side full bridge circuit including a first leg having a first electronic switch and a second electronic switch and a second leg having a third electronic switch and a fourth electronic switch, the method comprising:
controlling duty cycles of the first electronic switch and the second electronic switch of the first leg such that a duty cycle of one of the first electronic switch and the second electronic switch is greater than 50%, wherein the first electronic switch and the second electronic switch have complementary duty cycles;
controlling duty cycles of the third electronic switch and the fourth electronic switch of the second leg, such that a duty cycle of one of the third electronic switch and the fourth electronic switch is greater than 50%, wherein the third electronic switch and the fourth electronic switch have complementary duty cycles, wherein configurations of the first electronic switch, the second electronic switch, the third electronic switch, and the fourth electronic switch define an operating cycle pattern for the primary side full bridge circuit; and
after N cycles of the operating cycle pattern:
inverting the duty cycles of the first electronic switch and the second electronic switch of the first leg; and
inverting the duty cycles of the third electronic switch and the fourth electronic switch of the second leg.

10. The method of claim 9, comprising:
maintaining a phase angle of 180 degrees between an electronic switch of the first leg and an electronic switch of the second leg.

11. The method of claim 9, wherein the secondary side power stage circuit includes a secondary side full bridge circuit, and wherein the two-level DC-DC converter is a dual-active bridge circuit.

12. The method of claim 11, wherein the secondary side full bridge circuit is a two-level circuit.

13. The method of claim 9, wherein the secondary side power stage circuit includes a rectifier circuit, and wherein the two-level DC-DC converter is a single active full bridge circuit.

14. The method of claim 9, comprising:
controlling an operation of the first electronic switch, the second electronic switch, the third electronic switch, and the fourth electronic switch to use a first zero state, a second zero state, a third zero state, and a fourth zero state within the operating cycle pattern so as to balance a number of times the first electronic switch, the second electronic switch, the third electronic switch, and the fourth electronic switch are used.

15. The method of claim 14, wherein controlling the operation of the first electronic switch, the second electronic switch, the third electronic switch, and the fourth electronic switch to use the first zero state, the second zero state, the third zero state, and the fourth zero state within the operating cycle pattern so as to balance the number of times the first electronic switch, the second electronic switch, the third electronic switch, and the fourth electronic switch are used is configured for:
controlling the operation of the first electronic switch, the second electronic switch, the third electronic switch, and the fourth electronic switch to generate the operating cycle pattern of:
the first zero state, an active positive state, the second zero state, an active negative state, the third zero state, the active positive state, the fourth zero state, and the active negative state.

16. A control circuit for a two-level DC-DC converter, the two-level DC-DC converter including a primary side full bridge circuit having a first leg having a first electronic switch and a second electronic switch, and a second leg having a third electronic switch and a fourth electronic switch, wherein the primary side full bridge circuit is configured to generate a first voltage, and wherein configurations of the first electronic switch, the second electronic switch, the third electronic switch, and the fourth electronic switch define an operating cycle pattern, the two-level DC-DC converter further including a secondary side power stage circuit including a second plurality of electronic components, the secondary side power stage circuit configured to generate a second voltage, a transformer coupled between the primary side full bridge circuit and the secondary side power stage circuit, the control circuit comprising:
a PI controller and a duty cycle control circuit configured for:
controlling duty cycles of the first electronic switch and the second electronic switch of the first leg such that a duty cycle of one of the first electronic switch and the second electronic switch is greater than 50%, wherein the first electronic switch and the second electronic switch have complementary duty cycles;
controlling duty cycles of the third electronic switch and the fourth electronic switch of the second leg, such that a duty cycle of one of the third electronic switch and the fourth electronic switch is greater than 50%, wherein the third electronic switch and the fourth electronic switch have complementary duty cycles; and
after N cycles of the operating cycle pattern:
inverting the duty cycles of the first electronic switch and the second electronic switch of the first leg; and
inverting the duty cycles of the third electronic switch and the fourth electronic switch of the second leg.

17. The control circuit of claim 16, wherein the control circuit is configured for:
maintaining a phase angle of 180 degrees between an electronic switch of the first leg and an electronic switch of the second leg.

18. The control circuit of claim 16, wherein the control circuit is configured for:
controlling an operation of the first electronic switch, the second electronic switch, the third electronic switch, and the fourth electronic switch to use a first zero state, a second zero state, a third zero state, and a fourth zero state within the operating cycle pattern so as to balance a number of times the first electronic switch, the second electronic switch, the third electronic switch, and the fourth electronic switch are used.

19. The control circuit of claim 18, wherein the control circuit configured for controlling the operation of the first electronic switch, the second electronic switch, the third electronic switch, and the fourth electronic switch to use a first zero state, a second zero state, a third zero state, and a fourth zero state within the operating cycle pattern so as to balance the number of times the first electronic switch, the second electronic switch, the third electronic switch, and the fourth electronic switch are used is configured for:
controlling the operation of the first electronic switch, the second electronic switch, the third electronic switch, and the fourth electronic switch to generate the operating cycle pattern of:
the first zero state, an active positive state, the second zero state, an active negative state, the third zero state, the active positive state, the fourth zero state, and the active negative state.

20. The control circuit of claim 18, wherein the first electronic switch and the third electronic switch are coupled with a positive voltage rail, wherein the second electronic switch and the fourth electronic switch are coupled with a negative voltage rail,
wherein the first zero state includes:
one of the second electronic switch and the fourth electronic switch in an ON state and the other of the second electronic switch and the fourth electronic switch in an OFF state, and
both the first electronic switch and the third electronic switch in the OFF state, and
wherein the second zero state includes:
one of the first electronic switch and the third electronic switch in an ON state and the other of the first electronic switch and the third electronic switch in an OFF state, and
both the second electronic switch and the fourth electronic switch in the OFF state.
